(19) United States
(12) Patent Application Publication
(10) Pub. No.: US 2006/0107989 A1
(43) Pub. Date: May 25, 2006

(54) High watt density thermoelectrics

(75) Inventors: James L. Bierschenk, Rowlett, TX (US); Joshua E. Moczygemba, Wylie, TX (US); Tracy H. Aydelott, Sumner, TX (US)

Correspondence Address: BAKER BOTTS L.L.P., 2001 ROSS AVENUE, SUITE 600, DALLAS, TX, 75201-2980, US

(73) Assignee: MARLOW INDUSTRIES, INC.

(21) Appl. No.: 10/998,113

(22) Filed: Nov. 24, 2004

(51) Int. Cl. H01L 35/30; H01L 35/28

(52) U.S. Cl. 136/212; 136/205

(57) ABSTRACT

In accordance with one embodiment of the present invention, a method of manufacturing a thermoelectric device is disclosed. The method includes forming a wafer of thermoelectric material and coupling the wafer to a stiff backing such that a bottom side of the wafer faces the stiff backing and a top side of the wafer faces away from the stiff backing. The method also includes reducing a thickness of the wafer by removing a portion of the wafer from the top side, and dicing the wafer into a plurality of blocks. At least a portion of the plurality of blocks are then coupled with a permanent substrate.

### TECHNICAL FIELD OF THE INVENTION

This invention relates in general to a system and method for manufacturing thermoelectric elements, and more particularly to high watt density thermoelectrics.

### BACKGROUND OF THE INVENTION

The basic theory and operation of thermoelectric devices has been developed for many years. Presently available thermoelectric devices used for cooling typically include an array of thermocouples which operate in accordance with the Peltier effect. Thermoelectric devices may also be used for heating, power generation and temperature sensing.

Thermoelectric devices may be described as essentially small heat pumps which follow the laws of thermodynamics in the same manner as mechanical heat pumps, refrigerators, or any other apparatus used to transfer heat energy. A principal difference is that thermoelectric devices function with solid state electrical components (thermoelectric elements or thermocouples) as compared to more traditional mechanical/fluid heating and cooling components.

Thermoelectric materials such as alloys of Bi₂Te₃, PbTe and BiSb were developed thirty to forty years ago. More recently, semiconductor alloys such as SiGe have been used in the fabrication of thermoelectric devices. Typically, a thermoelectric device incorporates both a P-type semiconductor and an N-type semiconductor alloy as the thermoelectric materials.

As cooling applications progressively require smaller thermoelectric devices, existing manufacturing techniques have been unable to produce effective solutions.

### SUMMARY OF THE INVENTION

In accordance with the present invention, the disadvantages and problems associated with manufacturing thermoelectric modules with thin thermoelectric elements have been substantially reduced or eliminated. In particular, a method is provided which allows manufacturing of thin thermoelectric elements by coupling the elements to a stiff backing so the thermoelectric material may be more easily processed.

In accordance with one embodiment of the present invention, a method of manufacturing a thermoelectric device is disclosed. The method includes forming a wafer of thermoelectric material and coupling the wafer to a stiff backing such that a bottom side of the wafer faces the stiff backing and a top side of the wafer faces away from the stiff backing. The method also includes reducing a thickness of the wafer by removing a portion of the wafer from the top side, and dicing the wafer into a plurality of blocks. At least a portion of the plurality of blocks are then coupled with a permanent substrate. In certain embodiments the stiff backing may be a thermally conductive and electrically conductive metal plate.

In accordance with another embodiment of the present invention, a method of manufacturing a thermoelectric device may include cutting a wafer of thermoelectric material from a block or ingot of thermoelectric material. A first nickel diffusion barrier may then be applied to the wafer. The method may then include soldering a copper metal plate to the wafer such that a bottom side of the wafer faces the copper metal plate and a top side of the wafer faces away from the copper metal plate. A thickness of the wafer may then be reduced to less than 0.006 inches by lapping the wafer. The method may also include applying a second nickel diffusion barrier to the combination of the wafer and the copper metal plate, and dicing the combination of the wafer and the copper metal plate into a plurality of blocks. At least a portion of the plurality of blocks may be coupled with a permanent substrate.

In accordance with another embodiment of the present invention, a thermoelectric module, is provided. The module may include a substrate with a plurality of blocks coupled to it. A first portion of the plurality of blocks may be blocks of thermoelectric material, and a second portion of the plurality of blocks may include a first section of thermoelectric material coupled to a second section of conductive material. In certain embodiments the second portion of conductive material may be a thermally conductive and electrically conductive material.

Technical advantages of certain embodiments of the present invention include enabling production of thermoelectric elements which are thinner than traditional manufacturing methods are capable of achieving. Some thermoelectric materials become brittle or break when thinned past a threshold thickness. Coupling the thermoelectric material to a stiff backing provides support to the thermoelectric material and allows the thermoelectric material to be thinned to a point beyond which it may have been expected to break without the stiff backing.

Other technical advantages of certain embodiments of the present invention include using a stiff backing which is electrically and thermally conductive. In this manner the thermoelectric material does not need to be removed from the stiff backing, but may be diced into thermoelectric elements while still coupled to the stiff backing. This may result in thermoelectric elements (thermoelectric material and stiff backing) which are sufficiently large to be assembled into thermoelectric modules utilizing traditional systems or methods such as vide loading or pick-and-placing.

Other technical advantages of the present invention will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

For a more complete understanding of the present invention and its advantages, reference is now made to the following description, taken in conjunction with the accompanying drawings, in which:

FIG. 1 illustrates an isometric view of a thermoelectric device having multiple thermoelectric elements;

FIG. 2 is an electrical schematic drawing of one thermocouple of the thermoelectric device of FIG. 1;

FIG. 3 illustrates an isometric view of a thermoelectric device having multiple thermoelectric elements, each element being coupled to a conductive block of material;

FIG. 4 illustrates a side view of a particular embodiment of a device to be cooled and supporting hardware;

FIG. 5 illustrates a top view of a layout of a thermoelectric array in accordance with a particular embodiment of the present invention;

FIGS. 6A-6B illustrate top views of the electrical connections which may be present on upper and lower substrates to electrically couple the thermoelectric array of FIG. 5;

FIG. 7 illustrates a top view of the combination of the thermoelectric array of FIG. 5 with the electrical connections of FIGS. 6A and 6B;

FIGS. 8A-8B illustrate side views of two embodiments of thermoelectric elements made in accordance with the teachings of the present invention;

FIGS. 9A-9E illustrate a method of manufacturing thermoelectric elements having a thin wafer of thermoelectric material; and

FIG. 10 is a flow chart illustrating a method of manufacturing thermoelectric elements having a thin wafer of thermoelectric material.

### DETAILED DESCRIPTION OF THE INVENTION

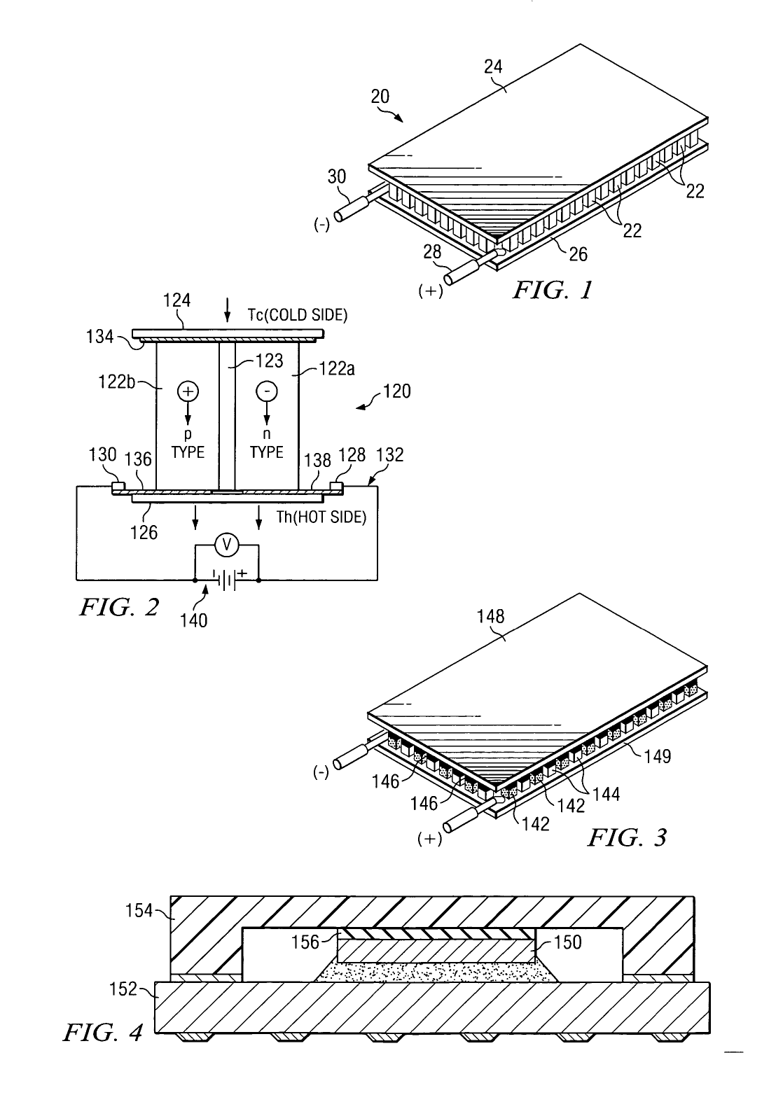

FIG. 1 illustrates a thermoelectric device 20 including a plurality of thermoelectric elements 22 disposed between a cold plate 24 and a hot plate 26. Electrical connections 28 and 30 are provided to allow thermoelectric device 20 to be electrically coupled with an appropriate source of DC electrical power.

Thermoelectric device 20 may be used as a heater, cooler, electrical power generator, and/or temperature sensor. If thermoelectric device 20 were designed to function as an electrical power generator, electrical connections 28 and 30 would represent the output terminals from such a power generator operating between hot and cold temperature sources.

FIG. 2 is a schematic representation of an electrical circuit 132 of a single stage thermoelectric device 120. Electrical circuit 132 may also be incorporated into thermoelectric elements or thermocouples to convert heat energy into electrical energy. Electrical circuit 132 generally includes two or more thermoelectric elements 122 fabricated from dissimilar semiconductor materials such as N-type thermoelectric elements 122a and P-type thermoelectric elements 122b. Thermoelectric elements 122 are typically configured in a generally alternating N-type element to P-type element arrangement and typically include an air gap 123 disposed between adjacent N-type and P-type elements. In many thermoelectric devices, thermoelectric materials with dissimilar characteristics are connected electrically in series and thermally in parallel.

Examples of thermoelectric devices and methods of fabrication are shown in U.S. Pat. No. 5,064,476 entitled Thermoelectric Cooler and Fabrication Method; U.S. Pat. No. 5,171,372 entitled Thermoelectric Cooler and Fabrication Method; and U.S. Pat. No. 5,576,512 entitled Thermoelectric Apparatus for Use With Multiple Power Sources and Method of Operation.

N-type semiconductor materials generally have more electrons than necessary to complete the associated crystal lattice structure. P-type semiconductor materials generally have fewer electrons than necessary to complete the associated crystal lattice structure. The “missing electrons” are sometimes referred to as “holes.” The extra electrons and extra holes are sometimes referred to as “carriers.” The extra electrons in N-type semiconductor materials and the extra holes in P-type semiconductor materials are the agents or carriers which transport or move heat energy between cold side or cold plate 124 and hot side or hot plate 126 through thermoelectric elements 122 when subject to a DC voltage potential. These same agents or carriers may generate electrical power when an appropriate temperature difference is present between cold side 124 and hot side 126.

In thermoelectric device 120, alternating thermoelectric elements 122a, and 122b of N-type and P-type semiconductor materials may have their ends connected by electrical conductors such as 134, 136 and 138. Conductors 134, 136 and 138 may be metalizations formed on thermoelectric elements 122a, 122b and/or on the interior surfaces of plates 124 and 126. Ceramic materials are frequently used to manufacture plates 124 and 126 which define in part the cold side and hot side, respectively, of thermoelectric device 120. Commercially available thermoelectric devices which function as a cooler generally include two ceramic plates with separate P-type and N-type thermoelectric elements formed from bismuth telluride (Bi₂, Te₃) alloys disposed between the ceramic plates and electrically connected with each other.

When DC electrical power from power supply 140 is properly applied to thermoelectric device 120 heat energy will be absorbed on cold side 124 of thermoelectric elements 122 and will be dissipated on hot side 126 of thermoelectric device 120. A heat sink or heat exchanger (sometimes referred to as a “hot sink”) may be attached to hot plate 126 of thermoelectric device 120 to aid in dissipating heat transferred by the associated carriers and phonons through thermoelectric elements 122 to the adjacent environment. In a similar manner, a heat sink or heat exchanger (sometimes referred to as a “cold sink”) may be attached to cold side 124 of thermoelectric device 120 to aid in removing heat from the adjacent environment. Thus, thermoelectric device 120 may sometimes function as a thermoelectric cooler when properly connected with power supply 140. However, since thermoelectric devices are a type of heat pump, thermoelectric device 120 may also function as a heater, power generator, or temperature sensor.

FIG. 3 is a schematic drawing showing an isometric view of a thermoelectric module having multiple thermoelectric elements. The thermoelectric elements include P-type elements 142 and N-type elements 144. Each thermoelectric element 142 and 144 is coupled to a conductive block of material 146. The combinations of thermoelectric elements 142 and 146 with conductive blocks of material 146 are then coupled between a hot plate 148 and a cold plate 149. The thermoelectric module is illustrated with all of conductive blocks of material 146 oriented upwards toward hot plate 148, and all of thermoelectric elements 142 and 146 oriented downwards towards cold plate 149. This orientation is for illustrative purposes only, and it would be understood by one of ordinary skill in the art that either an upward, downward, or mixed orientation of conductive blocks of material 146 and thermoelectric elements 142 and 146 would work equally well, if the conductive blocks have sufficiently high thermal conductivity.

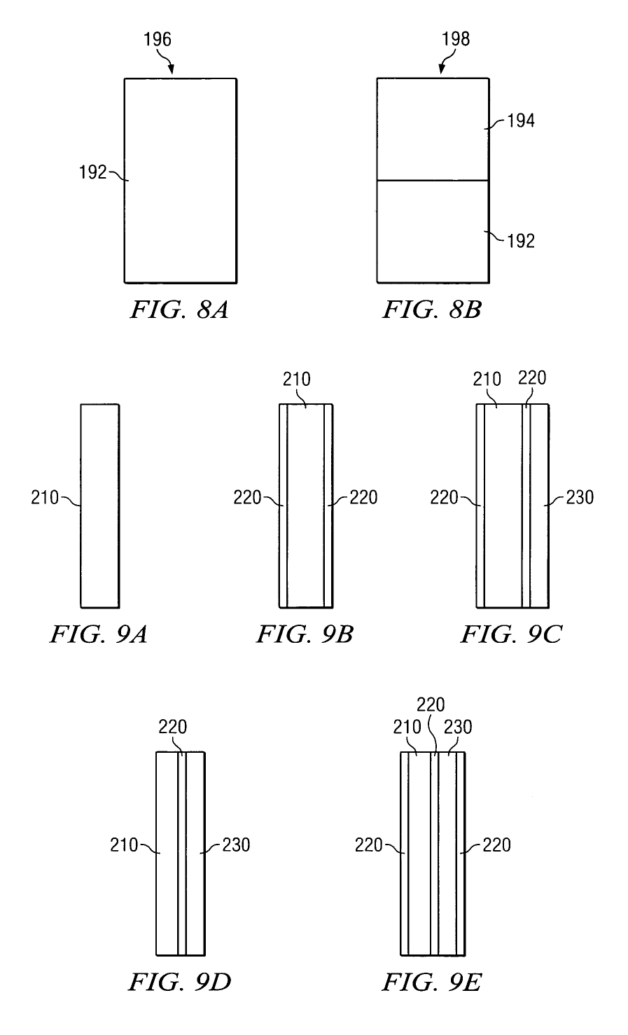

Coupling conductive blocks of material 146 to thermoelectric elements 142 and 146 may result in increased efficiency and/or greater heat transfer from cold plate 149 to hot plate 148. The reasons for this, as well as a description of one embodiment of a method of manufacturing the thermoelectric module of FIG. 3, will be described in more detail with regard to FIGS. 8-10.

When used as a cooler, a thermoelectric module may be known as a thermoelectric cooler. Thermoelectric coolers may be used to cool microelectronics. Heat generation from microelectronics continue to increase as chips become more powerful, utilizing higher clock speeds and ever increasing densities of transistors. The microelectronics industry is quickly reaching the limits of traditional air cooling for many applications. Failing to adequately dissipate the heat generated by these electronics may result in poor reliability, compromised performance, or permanent damage.

Thermoelectric coolers are one possible solution for helping keep microelectronics from getting too hot. Thermoelectric cooler power consumption is of concern since the input power to the thermoelectric cooler generates waste heat which may also need to be dissipated into the same heat sink as the heat from the electronic component. To minimize the input power to the thermoelectric cooler, the design of the thermoelectric cooler must be such that it affords operation near the theoretical maximum coefficient of performance for a given temperature difference across the thermoelectric cooler. The larger the temperature difference, the higher the input power and ultimately the higher the heat rejection. Operating at conditions far from the optimum coefficient of performance can significantly increase thermoelectric cooler power consumption. This has a compounding effect since the added heat from the thermoelectric cooler further raises the temperature of the heat sink, requiring the thermoelectric cooler to operate over an even larger temperature difference in order to provide a useful benefit.

The higher heat dissipation requirements are further compounded by the fact that the heat dissipation required by certain microelectronics may be non-uniform. This may be the case because heat generation within the microelectronic device itself is non-uniform. There may be local hot spots that should be kept below the device maximum temperature. Smaller sizes of microelectronic devices also complicate matters. As the devices get smaller, the heat loads become more concentrated. These non-uniformities and concentrated heat loads make it desirable to use higher efficiency heat sinks to dissipate the heat and to keep the peak temperatures from exceeding the maximum levels.

Higher and more concentrated heat loads (higher watt density loads) may require thermoelectric coolers which are fabricated with very short thermoelectric elements in order to operate near the maximum efficiency (closer to theoretical maximum coefficient of performance). These short elements may require the processing of thin wafers.

Additionally, thermoelectric coolers may be tailored so that their heat pumping capacity better matches the actual non-uniform heat load. This may result in an overall improvement in efficiency and lower power consumption and/or relatively cooler temperatures.

One use of a thermoelectric cooler in microelectronics would be to cool a heat generating microelectronic device, such as the die 150 illustrated in FIG. 4. FIG. 4 illustrates one embodiment of a die 150 which has been mounted to a circuit board 152 and is surrounded by an integrated heat spreader 154.

Integrated heat spreader 154 surrounds die 150 and may be thermally coupled to die 150 by a thermal interface material 156. The die may be packaged with an integrated heat spreader 154. Integrated heat spreader 154 is typically larger than die 150. Heat generated within die 150 is transferred through thermal interface material 156 and into integrated heat spreader 154. Integrated heat spreader 154 may be made of copper, aluminum, or other material with high conductivity. Integrated heat spreader 154 serves to spread the heat from the relatively smaller die 150 to a relatively larger area that may then contact the heat sink and/or thermoelectric cooler.

The heat generating device in FIG. 4 is merely one illustration of a possible heat generating device. Many other configurations are possible and are meant to fall within the scope of the present invention. In the illustrated configuration, a heat sink and/or thermoelectric cooler may be coupled to integrated heat spreader 154. In alternative embodiments, integrated heat spreader 154 may be much smaller, or integrated heat spreader 154 may be removed entirely and/or the heat sink and/or thermoelectric cooler may be coupled directly to die 150. A heat sink configuration for use in cooling the heat generating device illustrated in FIG. 4, or any configuration of heat generating device, may include the thermoelectric module illustrated in FIG. 1.

In one embodiment, die 150 may be a CPU die. CPU dies are designed to be smaller and more powerful than previous dies. This may result in greater heat generation from die 150 and an increase in the amount of heat to be dissipated. In addition, the higher density of heat being produced by the CPU results in larger temperature differences across the thermal interface material 156 and larger losses in the integrated heat spreader 154. Traditional heat sinks rely on passive air cooling to cool CPU dies. Die 150 could be actively cooled by coupling the thermoelectric module of FIG. 1, or any thermoelectric module, directly to CPU die 150, to integrated heat spreader 154, or to an additional thermal spreader between the integral heat spreader 154 and the thermoelectric module.

Adequate cooling of die 150 may be compounded if heat generation, and therefore heat dissipation, from die 150 is non-uniform. Portions of die 150 may generate more heat than other portions of die 150, and the result may be hot spots within die 150. The hot spots within die 150 should not exceed the maximum temperature for die 150. Therefore, a heat sink used to cool die 150 should be capable of dissipating enough heat to keep the hot spots of die 150 below this maximum temperature.

If a thermoelectric module is used as, or in conjunction with, a heat sink, cooling of the hot spots of die 150 may be achieved by passing a higher current through the thermoelectric elements of the thermoelectric module. Passing more current through the thermoelectric module would result in a greater temperature differential across the thermoelectric module. In this manner, the ability of the thermoelectric module to adequately cool die 150 could be increased. However, increasing the current which is passed through the thermoelectric elements of the thermoelectric module has the disadvantage of increasing the amount of heat which must be shunt from the combination of the die and the thermoelectric module. This is because the heat produced by the thermoelectric module may need to be dissipated into the same heat sink as the heat generated by the CPU die. Therefore, while increasing the current passed through the thermoelectric module is an option, it may be desirable to achieve adequate cooling of the hot spots of die 150 in a different manner.

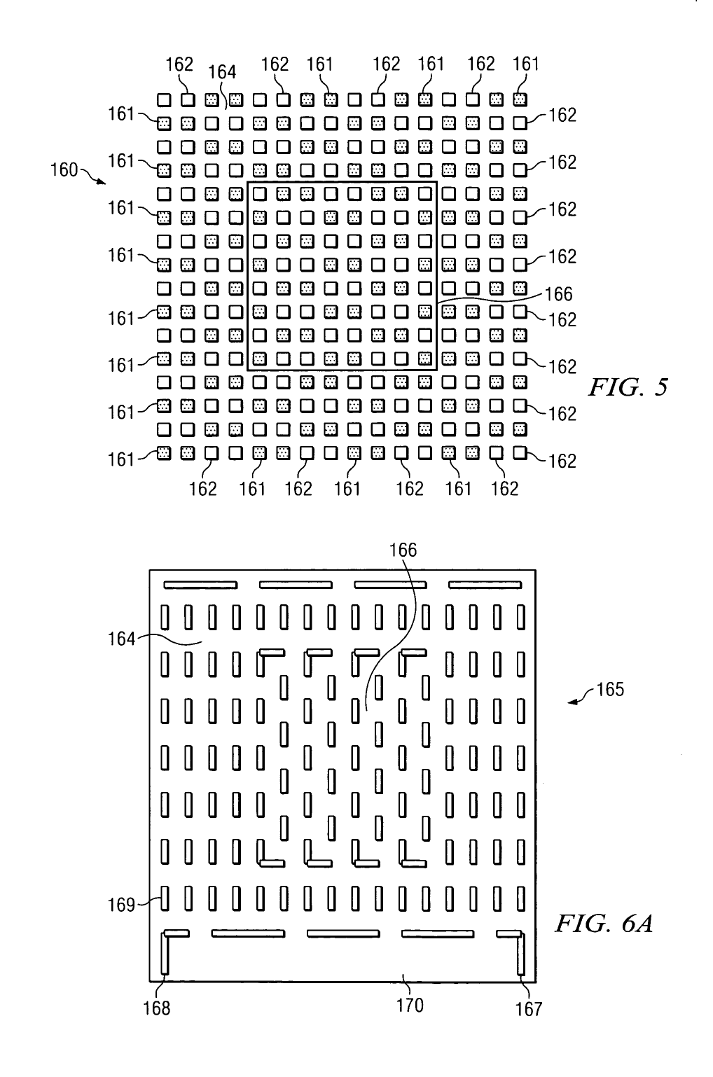

One embodiment of a thermoelectric cooler that may be used to cool a die with a non-uniform heat distribution is illustrated by FIGS. 5-7. Many dies exhibiting a non-uniform heat distribution will have the hottest hot spots at the center of the die. For this reason, the thermoelectric module illustrated in FIGS. 5-7 has been divided into an outer portion 164 and inner portion 166. The purpose of this division is to allow greater cooling of inner portion 166 relative to outer portion 164. That is, variable watt densities across the die may be matched with variable heat pumping capacity across the thermoelectric cooler.

FIG. 5 illustrates an array of thermoelectric elements 160. Thermoelectric array 160 includes P-type elements 161 and N-type elements 162. P-type elements 161 and N-type elements 162 are collectively referred to as thermoelectric elements 161 and 162. Thermoelectric elements 161 and 162 are arranged in both outer portion 164 and inner portion 166. The particular arrangement of thermoelectric elements 161 and 162 illustrated by FIG. 5 may allow for thermoelectric elements 161 and 162 of outer portion 164 to be electrically coupled in parallel rows while thermoelectric elements 161 and 162 in inner portion 166 may be connected in series.

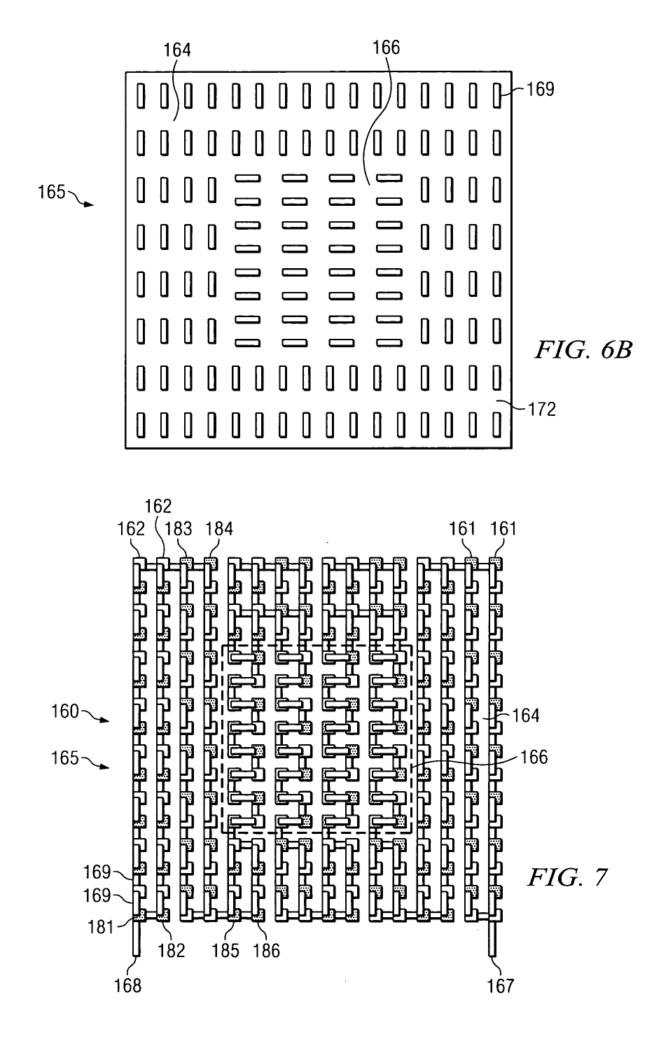

FIGS. 6A and 6B illustrate one embodiment of electrical connection layout 165 which may be applied to thermoelectric array 160 of FIG. 5. The electrical connections 169 present on base ceramic 170 are meant to work in conjunction with the electrical connections 169 on the top ceramic 172 to electrically couple the thermoelectric elements of thermoelectric array 160. Electrical connection layout 165 may be used to electrically couple the rows of outer portion 164 in parallel while coupling the thermoelectric elements of inner portion 166 in series. In the illustrated embodiment of FIGS. 6A and 6B, electrical connections 169 have different configurations on base ceramic 170 and top ceramic 172. In alternative embodiments, the electrical connections 169 on base ceramic 170 and top ceramic 172 could take any desired configuration to electrically couple the thermoelectric elements 161 and 162 in practically any desired configuration. In one embodiment, electrical connections 169 may be patterned metallizations which are sprayed, printed, machined, or etched onto base ceramic 170 and top ceramic 172. FIG. 6A also illustrates base ceramic 170 with electrode 167 and electrode 168. In alternative embodiments, electrodes 167 and 168 could be present on top ceramic 172 rather than base ceramic 170, or could be split between base ceramic 170 and top ceramic 172.

FIG. 7 illustrates a combination of thermoelectric array 160 of FIG. 5 with electrical connection layout 165 of FIGS. 6A and 6B. Specifically, the electrical connection layout 165 of base ceramic 170 has been overlaid with thermoelectric array 160. This combination has then been overlaid with electrical connection layout 165 of top ceramic 172. As can be seen in FIG. 7, the thermoelectric elements 161 and 162 of first row 181 have been electrically coupled in series and the thermoelectric elements 161 and 162 of second row 182 have also been electrically coupled in series. As can also be seen in FIG. 7, first row 181 has been electrically coupled with second row 182 in parallel. With this configuration, current may flow into electrode 168 and be split between first row 181 and second row 182. In this manner, first row 181 and second row 182 each have approximately half of the current flowing through them that flows through electrode 168.

At the end of first row 181 and second row 182, the current is once again combined and passed to third row 183 and fourth row 184. The combined current is then divided between third row 183 and fourth row 184. This is because third row 183 and fourth row 184 are also electrically coupled in parallel. In this manner approximately half of the current flowing through electrode 168, flows through third row 183 and approximately half the current flowing through electrode 168 flows through fourth row 184.

After the current flows through third row 183 and fourth row 184, it is once again combined and passed to fifth row 185 and sixth row 186. Fifth row 185 and sixth row 186 differ from first row 181, second row 182, third row 183, and fourth row 184 because fifth row 185 and sixth row 186 each pass through inner portion 166. Each of first-fourth rows 181-184 are disposed only in outer portion 164. The first portion of fifth row 185 and sixth row 186 and the last portion of these two rows run through outer portion 164. A middle portion of these two rows is disposed within inner portion 166. The portions of fifth row 185 and sixth row 186 that run through outer portion 164 are run in parallel with each other.

When fifth row 185 and sixth row 186 enter inner portion 166, thermoelectric elements 161 and 162 of fifth row 185 and sixth row 186 are no longer electrically coupled in series within the rows and in parallel between the rows but are now electrically coupled in series between the rows. In this manner, the half of the current that was traveling through fifth row 185 combines with the half of the current that was flowing through sixth row 186 as the rows enter inner portion 166. As the current flows through inner portion 166, each of the elements in fifth row 185 and sixth row 186 have the full current flowing through electrode 168, flowing through them. This current is once again split into two approximately half currents once fifth row 185 and sixth row 186 exit inner portion 166 and re-enter outer portion 164. This pattern continues for each of the rows passing through inner portion 166. The remainder of the rows which do not pass through inner portion 166 may be run in parallel configuration in the same manner as first row 181 and second row 182.

In a particular example of the above described embodiment, 10 amps may flow through electrode 168. This 10 amps could be divided between first row 181 and second row 182. The current will then be combined at the ends of first row 181 and 182. Third row 183 and fourth row 184 will then each receive approximately 5 amps. Fifth row 185 and sixth row 186 would also receive 5 amps for the portions of these rows that are disposed within outer portion 164. Once passing into inner portion 166, each thermoelectric element of fifth row 185 and sixth row 186 would once again receive 10 amps. This current would again be divided upon exiting inner portion 166.

In this manner each of the thermoelectric elements present in outer portion 164 receives half of the current that is received by the thermoelectric elements of inner portion 166. Utilizing this configuration, inner portion 166 is able to transfer heat at a greater rate than outer portion 164. This is because a thermoelectric element's ability to pump heat is directly proportional to the current passing through it. In other words, as the amount of current passed through a thermoelectric is increased, the amount of heat being pumped by the thermoelectric element is also increased.

The embodiment illustrated in FIGS. 5-7 is designed to cool a die with a hot spot present at approximately the center of the die. Alternative embodiments could be easily designed to cool dies with more than one hot spot or with hot spots that are not located around the center of the die. In these embodiments, multiple groupings of thermoelectric elements electrically coupled in series could be placed throughout thermoelectric element array 160. In an embodiment of the die that has one non-central hot spot, inner portion 166 could be relocated to be present in any part of thermoelectric array 160.

The embodiment illustrated in FIGS. 5-7 couples each of the outer rows in parallel with a second outer row. In alternative embodiments, the outer rows may be coupled in parallel sets of three or more rows. Further, the outer most rows may be grouped in parallel with more rows than are rows closer to the center, thereby providing greater current, and heat pumping ability, to the rows closer to the center. This may be used with or without the series configuration at the center of a thermoelectric element array. Further, the parallel circuits may be arranged other than in straight parallel rows. For instance, the parallel rows may wrap around a central portion of the thermoelectric array in a circular or square pattern.

The scope of the present invention is not intended to be limited to the specific embodiments described above, but is meant to encompass series/parallel configurations of thermoelectric elements where the areas with the highest heat load are coupled in series and the lower heat load areas are coupled in parallel. Further, in the areas including parallel circuit configurations, areas of relatively greater heat load may include fewer parallel circuits while areas of relatively less heat load may include more parallel circuits.

An embodiment of the present invention that may be used in lieu of or in conjunction with the embodiment illustrated in FIGS. 5-7 includes multiple electrical circuits powering individual sections of the thermoelectric cooler independently. The higher heat load areas could be provided with a higher current. In this manner, the heat pumping ability of different sections of the thermoelectric array could be tailored as needed to appropriately cool a target device. This approach may require separate electrical circuits, separate electrical connections, separate thermal control and separate power supplies for each section. Such implementation could be used with or without the series configuration of inner portion 166 or the parallel configuration of the rows of outer portion 164.

Another embodiment of the present invention that may be used in lieu of or in conjunction with the embodiment illustrated in FIGS. 5-7 includes varying the thermoelectric element spacing and/or packing density. The thermoelectric elements in the area needing greater cooling may be more tightly spaced. The thermoelectric elements in the areas requiring less heat transfer may be spaced more loosely. In other words, thermoelectric elements may be spaced closer together in areas with higher heat flux and spaced further apart in areas with lower heat flux. In the example illustrated in FIG. 7, this could be implemented by moving the thermoelectric elements in inner portion 166 closer together while leaving the outer portion 164 at its original spacing. Such implementation could be used with or without the series configuration of inner portion 166 or the parallel configuration of the rows of outer portion 164.

A further alternative embodiment of the present invention that may be used in lieu of or in conjunction with the embodiment described in FIGS. 5-7 may include varying the thermoelectric element cross-section. Varying the thermoelectric element cross section in different sections of the thermoelectric cooler may allow the heat pumping ability of the thermoelectric cooler to better match device heat loading. In many embodiments, it may be beneficial to keep all thermoelectric elements substantially the same height to simplify assembly. Thermoelectric elements with a larger cross-section may be used in areas requiring greater heat transfer and thermoelectric elements with a smaller cross-section may be used in portions requiring less heat transfer. Referring to FIG. 7, thermoelectric elements with larger cross-sections may be placed in inner portion 166, while thermoelectric elements with smaller cross-sections may be placed in outer portion 164. Such implementation could be used with or without the series configuration of inner portion 166 or the parallel configuration of the rows of outer portion 164.

Another further alternative embodiment of the present invention which could be used in conjunction with or in lieu of the embodiment illustrated in FIGS. 5-7 may include varying the properties of the thermoelectric elements and construction materials in the portion that requires greater heat transfer. This may involve using higher ZT performance thermoelectric materials, such as Bi₂Te₃ or materials not yet developed, using an improved contact barrier, such as nickel or materials not yet developed, or modifying other variables that impact cost and/or performance. As some of these materials may be more expensive, it may be desirable to use them in only the relatively critical, high impact sections of the thermoelectric cooler. Implementing this in the embodiment illustrated by FIG. 7 may involve using the higher performance materials in only inner portion 166. Such implementation could be used with or without the series configuration of inner portion 166 or the parallel configuration of the rows of outer portion 164.

In certain embodiments, using the highest heat pumping thermoelectric elements in regions of relatively lower heat loading may not be justified. Certain thermoelectric elements, such as, for example, thermoelectric elements 198, may have higher contact resistance losses and higher interconnect losses than a traditional thermoelectric element, such as, for example thermoelectric element 196. Therefore, it may be desirable to use the former type of elements in areas where the benefits of elevated heat pumping ability outweigh the drawbacks of elevated contact resistance losses and interconnect losses. As contact barriers improve and interconnect losses are decreased, the regions which can efficiently benefit from the higher heat pumping thermoelectric elements may increase. Even as the range of efficient use of the higher heat pumping thermoelectric elements is increased, the varied cooling requirements across a surface of an object to be cooled may be best met by a mixture of thermoelectric elements as taught by one of the embodiments described herein.

An additional alternative embodiment of the present invention which could be used in conjunction with or in lieu of the embodiment illustrated in FIGS. 5-7 may include both active and passive cooling systems coupled with the device. Part of the heat may be pumped by a thermoelectric cooler inner core and the lower heat load areas could be handled passively without a TEC (simply connected to the heat sink—only the center highest watt density areas would utilize the thermoelectric cooler). Implementing this in the embodiment illustrated by FIG. 7 would involve removing the thermoelectric elements from outer portion 164. Such implementation could be used with or without the series configuration of inner portion 166.

In many of the above-described embodiments, the height of the thermoelectric elements present in thermoelectric array 160 may be constant across the thermoelectric array 160. In other words, the height of each thermoelectric element is substantially the same as the height of every other thermoelectric element. In this discussion, the height of the thermoelectric element would be the dimension of the thermoelectric element between base ceramic 170 and top ceramic 172. Such a configuration would allow base ceramic 170 to be approximately parallel to top ceramic 172 while contacting each thermoelectric element.

In a particular embodiment, each of the thermoelectric elements may not be the same height. Differences in the heights of the thermoelectric elements may be compensated for by using taller electrical connections in areas of shorter thermoelectric elements. Using taller electrical interconnections would allow the base ceramic 170 to be approximately parallel to top ceramic 172 while contacting each thermoelectric element.

In an alternative embodiment, the effective height of each thermoelectric element or selected thermoelectric elements could be changed by coupling a very short thermoelectric element with a thermally and electrically conductive material. FIG. 8A illustrates thermoelectric element 192, which is a solid block of thermoelectric material 192. FIG. 8B, on the other hand, illustrates thermoelectric element 198, which includes a much thinner block of thermoelectric material 192 coupled with a thermally and electrically conductive material 194. Thermoelectric elements 196 and 198 have the same height. However, thermoelectric element 198 has a shorter effective height. Thermoelectric element 198 has a shorter effective height because material 194, which may be, for example, copper or aluminum, is a better thermal conductor than the thermoelectric material 192, which might be, for example, Bi₂Te₃. FIG. 8B illustrates material 194 and thermoelectric material 192 having approximately equal dimensions. This is for illustrative purposes only, and material 194 and thermoelectric material 192 could be any size and proportion to each other. Thermoelectric elements 196 and 198 may be the same height. This enables either element to be easily used in conjunction with the other element within a single thermoelectric module. In this manner, thermoelectric element 198 may be selectively used in the areas requiring greater heat transfer. Thermoelectric element 196 may be used in the areas requiring less heat transfer. Looking back to FIG. 5, thermoelectric element array 160 may include thermoelectric elements 196 and 198. Thermoelectric element 198 may be used in inner portion 166 while thermoelectric elements 196 may be used in outer portion 164. Such implementation could be used with or without the series configuration of inner portion 166 or the parallel configuration of the rows of outer portion 164.

In an alternative embodiment, thermoelectric elements 198 may be used throughout the inner portion 166 and the outer portion 164. The thermoelectric elements in inner portion 166 may have the same or different effective heights than the thermoelectric elements 198 in outer portion 164. Further, thermoelectric elements 198 may be mixed with thermoelectric elements 196 to improve cooling throughout a thermoelectric array, or groups of thermoelectric elements 198 may be selectively placed in areas of greater heat load to improve cooling in those areas. Such implementation could be used with or without the series configuration of inner portion 166 or the parallel configuration of the rows of outer portion 164.

A method of manufacturing thermoelectric element 198 is illustrated by FIGS. 9A-9E. The method begins in FIG. 9A with a wafer of thermoelectric material 210. Wafer 210 may be sliced as thin as possible using traditional manufacturing techniques. In one embodiment, wafer 210 may be sliced between 0.010 inches and 0.030 inches in thickness. In an alternative embodiment, any thickness of wafer 210 may be used in FIG. 9A.

Wafer 210 may be sliced from a larger ingot or larger block of thermoelectric material using a diamond saw, ID saw, wire saw, or other appropriate cutting mechanism. The ingots from which the wafers are cut, can be produced in a variety of ways. These ways include crystal growth methods (such as Bridgman), plastic deformation (such as hot forging or extrusion), or pressing and sintering operations. Each ingot fabrication method has its own limitations on the dimensions from which high performance thermoelectric elements can be fabricated.

Generally, the thinner the material is the more fragile it becomes making it much more difficult and costly to handle. For example, traditional Bridgman materials are notoriously fragile at thin wafer thicknesses because of the cleavage planes that are inherent to the microstructure. For Bridgman materials, practical wafers in volume production are generally limited to about 0.75 mm (0.030″) thickness. Powder formed materials or plastically deformed material are much better and can be taken to thickness of around 0.25 mm (0.010″). The desired element thickness may be less than these values. Such is the case for high efficiency designs for high heat dissipation electronics or automotive air conditioning applications. In some of these applications, thickness of 0.125 mm (0.005″) or less may be desirable.

Once wafer 210 is formed, FIG. 9B demonstrates a diffusion barrier 220 being applied to wafer 210. Diffusion barrier 220 is generally made from materials such as nickel, and is used to prevent undesirable constituents in the solder or in the copper making up the electrical interconnecting pads from diffusion into the thermoelectric material, where they might change and/or degrade the performance of the thermoelectric material over time. In alternative embodiments, diffusion barrier 220 is not applied to wafer 210, but is applied to the copper electrical connecting pads instead.

FIG. 9C demonstrates wafer 210 being mounted to a stiff backing 230. In one embodiment, stiff backing 230 may be meant to be permanently mounted to wafer 210 and may include copper (Cu), nickel (Ni), molybdenum (Mo), and/or aluminum (Al). In alternative embodiments, stiff backing 230 could be temporarily mounted to wafer 210 and could be plastic, ceramic, epoxy, glass, or any other suitable material. Stiff backing 230 may be bonded to wafer 210 by an epoxy, soldering process, welding process, or diffusion bonding. Stiff backing 230 may also be deposited onto the wafer via sputtering, electroplating, or evaporation. The method chosen to couple wafer 210 to stiff backing 230 may depend on the properties of stiff backing 230 and whether stiff-backing 230 is intended to be permanent or temporary. Wafer 210 may be bonded to stiff-backing 230 such that one side of wafer 210 is accessible for thinning.

FIG. 9D demonstrates wafer 210 being thinned. Wafer 210 may be thinned using a lapping technique, abrading, chemical etching, or other appropriate system or method capable of thinning wafer 210 to the desired thickness. In one embodiment, wafer 210 may be thinned to 0.006 inches or less.

FIG. 9E demonstrates the application of a diffusion barrier 220 to either side of the combination of wafer 210 and stiff-backing 230. In a particular embodiment, diffusion barrier 220 may be nickel. In certain embodiments, where stiff-backing is not intended to be permanently mounted to wafer 210, diffusion barrier 220 may not be applied until after stiff-backing 230 has been removed. Once wafer 210 has been thinned to the desired thickness it may be diced into blocks. If stiff backing is intended to be permanently coupled to wafer 210, stiff backing may also be diced along with wafer 210. This dicing can occur using a diamond saw, ID saw, string saw, or any appropriate cutting method.

When stiff backing 230 is a thermally and electrically conductive material and is permanently mounted to wafer 210 and the combination is diced, the result is a block as illustrated in FIG. 8B. This method provides very short thermoelectric elements and therefore a maximum coefficient of performance of operation (i.e., high efficiency). The result of the method is thermoelectric elements which may be used in the fabrication of thermoelectric modules using traditional fabrication techniques. This method also opens new avenues for design, providing an easy means of producing thermoelectric modules with variable watt density capability to handle the non-uniform heat loads associated with dies having hot spots.

In a particular embodiment of the present invention, a second stiff backing may be coupled to the wafer such that the wafer is sandwiched between two stiff backings. The stiff backings may be the same or different materials and one or both of the stiff backings may be intended to be permanent or temporary. The second stiff backing may be coupled to the wafer prior to dicing such that the resulting thermoelectric elements have a thin section of thermoelectric material between two portions of the stiff backing.

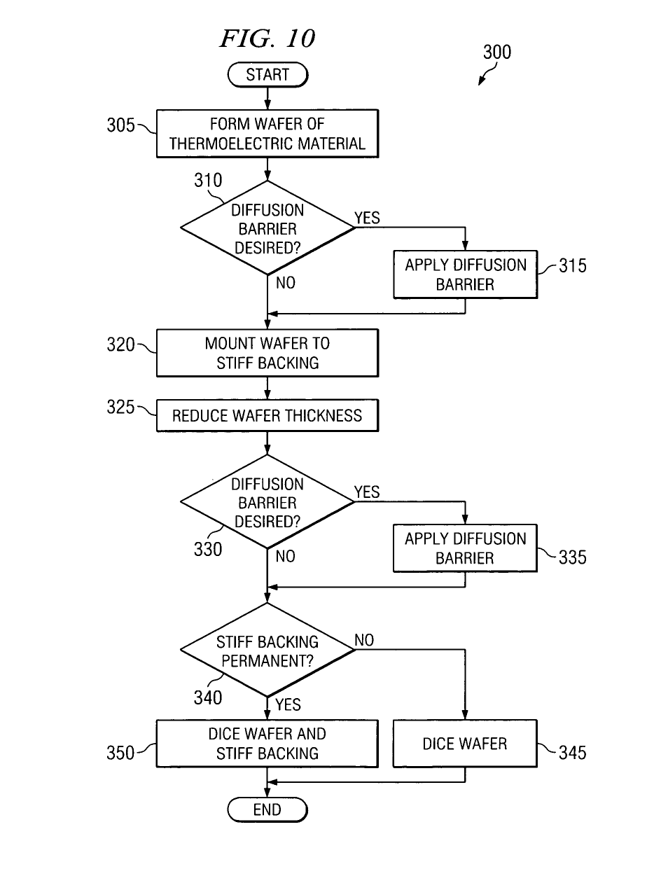

The above described method of manufacture is illustrated in flowchart form in FIG. 10. The method begins in step 305 by forming a wafer of thermoelectric material. Once the wafer is formed, a diffusion barrier may be applied, if desirable. This determination is made in step 310, and the diffusion barrier, if desired, is applied in step 315. If a diffusion barrier is not desired, or after application of the diffusion barrier if it is desired, the wafer is mounted to a stiff backing in step 320. In step 325 the wafer thickness is reduced. Step 330 illustrates a second decision to apply a diffusion barrier. If a diffusion barrier is desirable, it may be applied in step 335. After the decision in step 330 is made, step 340 demonstrates a decision as to whether the stiff backing is permanent. If the stiff backing is not permanent, the wafer may be diced as demonstrated in step 345. The wafer may be diced either before or after removal of the stiff backing. If the stiff backing is permanent, then the wafer and stiff backing may be diced in step 350.

This method may provide a way of producing high watt density thermoelectric coolers (because the coolers can be fabricated using very short elements). The technique may also allow creation of elements that can be assembled using typical thermoelectric cooler assembly processes (i.e. ones where P and N elements are either hand or machine loaded into tooling and soldered onto ceramics). The technique could also be used for devices fabricated from co-extruded materials (See U.S. patent application Ser. No. 10/729,610), or devices using Build-in-place assembly techniques (See U.S. patent application entitled Build-In-Place Method of Manufacturing Thermoelectric Modules, Ser. No. 10/966,685). The technique allows varying the element geometry within the thermoelectric cooler (thermoelectric material portion of elements can be shorter in some areas as part of TE element essentially replaced by metal conductor). The method also allows creation of elements that can be mass loaded instead of hand loaded because the effective length to width can be changed to make mass loading easier (i.e. to move the element geometry away from being cubic). The method may also produce higher reliability thermoelectric coolers as stress concentrations, typically present at the ends of the elements, can be moved from the weaker thermoelectric/diffusion barrier region to a region within the stronger metal conductor.

The foregoing discussion details an approach for achieving variable heat pumping within a thermoelectric cooler to better match a non uniform heat flux dissipated by an electronic component such as a computer CPU. The improved thermoelectric cooler operates at a higher efficiency and thereby improves its ability to effectively enhance the effectiveness of existing air cooled or water cooled heat sinks.

The foregoing discussion also details an approach to achieving very short thermoelectric elements, which allow maximum coefficient of performance operation (high efficiency), and still allow the thermoelectric cooler to be fabricated using traditional fabrication techniques. In addition, the element technique opens new avenues for design, providing an easy method of producing thermoelectric coolers with variable watt density to handle the non uniform heat loads associated with typical CPU dies.

Although the present invention has been described with several embodiments, a myriad of changes, variations, alterations, transformations, and modifications may be suggested to one skilled in the art, and it is intended that the present invention encompass such changes, variations, alterations, transformations, and modifications as fall within the scope of the appended claims.

What is claimed is:

1. A method of manufacturing short thermoelectric elements, comprising:
forming a wafer of thermoelectric material;
coupling the wafer to a stiff backing such that a bottom side of the wafer faces the stiff backing and a top side of the wafer faces away from the stiff backing;
reducing a thickness of the wafer by removing a portion of the wafer from the top side; and
dicing the wafer into a plurality of blocks.

2. The method of claim 1, wherein the wafer is formed by cutting the wafer from a block or ingot of thermoelectric material.

3. The method of claim 1, wherein the wafer is formed by hot pressing a block of thermoelectric material.

4. The method of claim 1, wherein the thickness of the wafer is between 0.007 inches and 0.035 inches before reducing the thickness of the wafer.

5. The method of claim 1, wherein the thickness of the wafer is reduced by a method selected from the group consisting of lapping, grinding, abrading, machining, and chemical etching.

6. The method of claim 1, wherein the thickness of the wafer is between 0.001 inches and 0.02 inches after reducing the thickness of the wafer.

7. The method of claim 1, wherein the thermoelectric material is bismuth telluride (Bi₂Te₃).

8. The method of claim 1, wherein a diffusion barrier is applied to the wafer prior to coupling the wafer to the stiff backing; and
wherein a diffusion barrier is applied to the wafer after reducing the thickness of the wafer.

9. The method of claim 8, wherein the diffusion barrier includes nickel (Ni).

10. The method of claim 1, wherein the stiff backing is a thermally conductive and electrically conductive metal plate.

11. The method of claim 10, wherein the stiff backing includes metal selected from the group consisting of copper (Cu), nickel (Ni), molybdenum (Mo), and aluminum (Al).

12. The method of claim 1, further comprising dicing the stiff backing while the stiff backing is coupled with the wafer.

13. The method of claim 12, further comprising mounting the stiff backing to the permanent substrate.

14. The method of claim 1, further comprising coupling at least a portion of the wafer with a permanent substrate

15. The method of claim 14, further comprising removing the stiff backing from the wafer prior to coupling the at least a portion of the wafer to the permanent substrate.

16. The method of claim 14, further comprising removing the stiff backing after the at least a portion of the wafer is mounted to the permanent substrate.

17. The method of claim 1, further comprising soldering the stiff backing to the wafer.

18. The method of claim 1, wherein the wafer is coupled to the stiff backing with epoxy.

19. The method of claim 1, further comprising diffusion bonding the stiff backing to the wafer.

20. The method of claim 1, wherein the stiff backing is coupled with the wafer by a method selected from the group consisting of sputtering, electroplating, and evaporating.

21. The method of claim 1, wherein the stiff backing includes material selected from the group consisting of plastic, ceramic, epoxy, and glass.

22. The method of claim 1, further comprising coupling a second stiff backing to the top of the wafer.

23. A method of manufacturing a thermoelectric device, comprising:
cutting a wafer of thermoelectric material from a block or ingot of thermoelectric material;
applying a first nickel diffusion barrier to the wafer;
soldering a copper metal plate to the wafer such that a bottom side of the wafer faces the copper metal plate and a top side of the wafer faces away from the copper metal plate;
lapping the top side of the wafer and thereby reducing a thickness of the wafer to less than 0.006 inches;
applying a second nickel diffusion barrier to the combination of the wafer and the copper metal plate;
dicing the combination of the wafer and the copper metal plate into a plurality of blocks; and
coupling at least a portion of the plurality of blocks with a permanent substrate.

24. A thermoelectric module, comprising:
a substrate;
a plurality of blocks coupled to the substrate;
wherein a first portion of the plurality of blocks are blocks of thermoelectric material; and
wherein a second portion of the plurality of blocks include a first section of thermoelectric material coupled to a second section of conductive material.

25. The thermoelectric module of claim 24, wherein each of the plurality of blocks is substantially the same height as other ones of the plurality of blocks.

26. The thermoelectric module of claim 24, wherein the first and second portions of the plurality of blocks include blocks of P-type thermoelectric material and blocks of N-type thermoelectric material.

27. The thermoelectric module of claim 26, wherein the blocks of P-type thermoelectric material are alternatingly arranged with the blocks of N-type thermoelectric material.

28. The thermoelectric module of claim 24, wherein the second portion of the plurality of blocks are arranged proximate other blocks of the second portion of the plurality of blocks such that groupings of blocks of the second portion of the plurality of blocks results.

29. The thermoelectric module of claim 24, wherein:
exposing the blocks to a current results in heat being transferred directionally from the substrate through the blocks; and
blocks of the second portion of the plurality of blocks transfer more heat than blocks of the first portion of the plurality of blocks.

30. The thermoelectric module of claim 24, wherein the second section of conductive material is a thermally conductive and electrically conductive material.

31. The thermoelectric module of claim 24, wherein the second section of conductive material includes metal selected from the group consisting of copper (Cu), nickel (Ni), molybdenum (Mo), and aluminum (Al).

32. A thermoelectric module, comprising:
a substrate;
a plurality of blocks coupled to the substrate;
wherein each of the plurality of blocks include a first section of thermoelectric material coupled to a second section of conductive material.

33. The thermoelectric module of claim 32, wherein each of the plurality of blocks is substantially the same height as other ones of the plurality of blocks.

34. The thermoelectric module of claim 32, wherein the second section of conductive material is a thermally conductive and electrically conductive material.

35. The thermoelectric module of claim 32, wherein the second section of conductive material includes metal selected from the group consisting of copper (Cu), nickel (Ni), molybdenum (Mo), and aluminum (Al).
